(19) United States
(12) Patent Application Publication
(10) Pub. No.: US 2003/0042614 A1
(43) Pub. Date: Mar. 6, 2003

(54) Metal silicide adhesion layer for contact structures

(76) Inventors: Ammar Deraa, Boise, ID (US); Sujit Sharan, Chandler, AZ (US); Paul Castrovillo, Boise, ID (US)

Correspondence Address: KNOBBE MARTENS OLSON & BEAR LLP, 2040 MAIN STREET, FOURTEENTH FLOOR, IRVINE, CA, 92614, US

(21) Appl. No.: 09/945,065

(22) Filed: Aug. 30, 2001

(51) Int. Cl. H01L 23/48

(52) U.S. Cl. 257/768

(57) ABSTRACT

A high aspect ratio contact structure using a metal silicide adhesion layer that is interposed between titanium and titanium nitride (TiN) to promote adhesion of TiN to Ti. The metal silicide adhesion layer created from silicon doped CVD Ti can be deposited over the unreacted Ti after the silicidation reaction or deposited directly on the silicon substrate in place of CVD Ti. The contact structure further includes contact fill that is comprised of TiCl₄ based TiN, which affords improved step coverage in the contact structure.

### RELATED APPLICATION

This application is related to co-pending U.S. Patent Application No. ______ filed ______ entitled “High Aspect Ratio Contact Structure With Reduced Silicon Consumption.”

### BACKGROUND OF THE INVENTION

1. Field of the Invention

This invention relates to integrated circuits, and more particularly, to a high aspect ratio contact structure with uniform step coverage and improved adhesion of contact fill.

2. Description of the Related Art

A high density integrated circuit typically includes numerous electrical devices and conductors formed on multiple layers of conducting and semiconducting material that are deposited and patterned in sequence onto a substrate surface. An integrated circuit is operable when its individual components are interconnected with an external source and with one another. In particular, designs of more complex circuits often involve electrical interconnections between components on different layers of circuit as well as between devices formed on the same layer. Such electrical interconnections between components are typically established through electrical contacts formed on the individual components. The contacts provide exposed conductive surfaces on each device where electrical connections can be made. For example, electrical contacts are usually made among circuit nodes such as isolated device active regions formed within a single-crystal silicon substrate. However, as the contact dimensions of devices become smaller, the contact resistance and the sheet resistance of the contacts also increase.

To address this problem, refractory metal silicides have been used for local interconnections to provide low resistance electrical contacts between device active regions within the silicon substrate. One common method of forming metal suicides is a self-aligned silicide process, often referred to as silicidation. In this process, a thin layer of refractory metal, such as titanium, is deposited over a dielectric area and through contact openings formed on the dielectric area to contact underlying silicon circuit elements, such as a source and drain active regions formed within a silicon substrate. The structure is then annealed to form a silicide, such as titanium silicide (TiSiₓ), at a high temperature. During annealing, the deposited titanium reacts with the silicon in the substrate to form TiSiₓ inside the contact openings adjacent the active regions. The titanium and silicon react with each other to form a silicide thick enough to provide low sheet resistance. The process is referred to as “self-aligning” because the TiSiₓ is formed only where the metal layer contacts silicon, for example, through the contact openings. As such, titanium that overlies the dielectric areas surrounding the contact openings, along the sidewalls of the openings, and any other non-silicon surfaces remains unreacted.

The conventional silicidation process is not entirely suitable for devices having relatively shallow contact junctions. Shallow junction structures may be damaged when the silicidation reaction consumes a disproportionate amount of silicon from the relatively shallow junction region. To address this problem, a titanium silicide film can be directly deposited on the silicon substrate to reduce silicon consumption in the junction area. The TiSiₓ film can be deposited using low pressure chemical vapor deposition (LPCVD) or chemical vapor deposition (CVD) processes. However, there are numerous disadvantages associated with these conventional methods of forming a TiSiₓ film on the substrate. For example, the LPCVD process typically requires reaction temperatures in excess of 700 C. and the conventional CVD process tends to produce a TiSiₓ film with high bulk resistivity.

Moreover, subsequent to forming the TiSiₓ film, a diffusion barrier layer such as titanium nitride (TiN) is typically formed on the contact structure. The TiN layer inhibits subsequently deposited contact metal from diffusing into the insulating layer surrounding the contact structure. Typically, TiN is deposited on the TiSiₓ layer in the contact openings as well as on the unreacted Ti remaining on the dielectric layer and on the sidewalls of the contact openings. Disadvantageously, TiN forms a relatively weak bond with Ti and is likely to peel off from surfaces where TiN has contact with Ti. To address this problem, the Ti deposited on the dielectric layer and on the sidewalls of the contact opening can be removed prior to deposition of TiN. However, the Ti removal process is likely to add to the cost and complexity of the fabrication process.

Furthermore, once the diffusion barrier layer is formed, conductive contact fills such as tungsten can be deposited into the contact openings. The contact fills are typically deposited into the contact openings by physical deposition processes such as sputtering. However, the step coverage provided by sputtering and other physical deposition processes is often inadequate for high aspect ratio contact openings because it can be particularly difficult to physically deposit uniform layers of contact fill into high aspect ratio contact openings.

Hence, from the foregoing, it will be appreciated that there is a need for a method of improving the step coverage of contact fills in high aspect ratio contact structures. There is also a need for a contact structure having improved contact fill adhesion. Furthermore, there is also a need for a method of reducing silicon consumption in shallow junction regions during silicidation process. To this end, there is a particular need for a high aspect ratio contact structure that provides a more uniform step coverage and improved TiN adhesion. There is also a particular need for a method of reducing silicon consumption in shallow junction regions during the formation of the titanium silicide layer.

### SUMMARY OF THE INVENTION

In one aspect, the preferred embodiments of the present invention comprise an integrated circuit that utilizes a metal silicide adhesion layer to enhance the adhesion between metal and metal nitride in a contact opening. In one embodiment, the integrated circuit comprises a silicon substrate, an insulating layer formed over the silicon substrate wherein the insulating layer has an opening that extends from an upper surface of the insulating layer to an upper surface of the substrate. The integrated circuit further comprises a metal layer formed in the opening wherein a first portion of the metal layer is formed on the exposed upper surface of the substrate and reacts with silicon in the substrate to form metal silicide while a second portion of the metal layer does not contact the substrate and therefore remains unreacted with silicon. Furthermore, the integrated circuit comprises a metal nitride layer that is subsequently deposited over the first and second portions of the metal layer. To improve adhesion between the metal and metal nitride layer, a metal silicide adhesion layer is interposed between the metal nitride and the second portion of the metal layer. Advantageously, the metal silicide adhesion layer forms a durable bond between the metal nitride and the metal layer so as to reduce the occurrence of metal nitride peeling off of the metal layer.

In another aspect, the preferred embodiments of the present invention comprise a high aspect ratio contact structure formed over a junction region in a silicon substrate. Preferably, the contact structure comprises an insulating layer defining a contact opening that is formed over the junction region of the substrate. The contact structure further comprises a titanium layer formed in and adjacent the contact opening, wherein a first portion of the titanium layer is formed on the silicon substrate while a second portion is formed on the insulating layer. The contact structure further comprises a titanium silicide adhesion layer that is used to enhance the adhesion between the second portion of the titanium layer to a subsequently deposited titanium nitride (TiN) layer. Preferably, the contact structure further comprises a TiCl₄ based TiN contact fill, which provides a more uniform step coverage in high aspect ratio contact structures.

In yet another aspect, the preferred embodiments of the present invention comprise a method of forming a contact structure on a substrate. The method comprises depositing an insulating layer on an upper surface of the substrate and forming an opening in the insulating layer. Preferably, the opening extends from an upper surface of the insulating layer to the upper surface of the substrate. The method further comprises forming a titanium layer in and adjacent the opening such that a first portion of the titanium layer is formed on the upper surface of the substrate and a second portion of the titanium layer is formed on the upper surface of the insulating layer adjacent the opening.

In one embodiment, the first portion of the titanium layer reacts with silicon in the substrate to form titanium silicide adjacent the upper surface of the substrate. Moreover, a titanium suicide adhesion layer is subsequently deposited in and adjacent the contact opening, covering the second portion of the titanium layer deposited adjacent the insulating layer. In one embodiment, the titanium silicide adhesion layer is approximately 100 Å thick.

Advantageously, the titanium silicide adhesion layer enhances the adhesion between titanium and a subsequently formed titanium nitride layer. Furthermore, the titanium nitride preferably fills substantially the entire opening so as to form a TiN contact fill. Preferably, the method further comprises filling substantially the entire contact opening with TiN using a chemical deposition technique so that a uniform contact fill can be deposited even in high aspect ratio contact openings. These and other advantages of the present invention will become more fully apparent from the following description taken in conjunction with the accompanying drawings.

### BRIEF DESCRIPTION OF THE DRAWINGS

FIG. 1 illustrates a schematic cross sectional view of a partially fabricated integrated circuit of one preferred embodiment of the present invention;

FIG. 2 illustrates a schematic cross sectional view of the integrated circuit of FIG. 1, showing the formation of a metal layer in the contact opening;

FIG. 3 illustrates a schematic cross sectional view of the integrated circuit of FIG. 2, showing the formation of a metal silicide layer adjacent the substrate;

FIG. 4 illustrates a schematic cross sectional view of the integrated circuit of FIG. 3, showing the formation of a metal silicidation adhesion layer;

FIG. 5 illustrates a schematic cross sectional view of the integrated circuit of FIG. 4, showing the formation of a metal nitride diffusion layer;

FIG. 6 illustrates a schematic cross sectional view of the integrated circuit of FIG. 5, showing the formation of a contact fill in the contact opening.

### DETAILED DESCRIPTION OF THE PREFERRED EMBODIMENT

References will now be made to the drawings wherein like numerals refer to like parts throughout. While the preferred embodiments are illustrated in the context of contact openings over active regions in silicon substrates, it will be recognized by one skilled in the art of semiconductor fabrication that the invention will have application whenever electrical contact to silicon elements is desirable. Furthermore, the term “substrate” as used in the present application, refers to one or more semiconductor layers or structures which include active or operable portions of semiconductor devices.

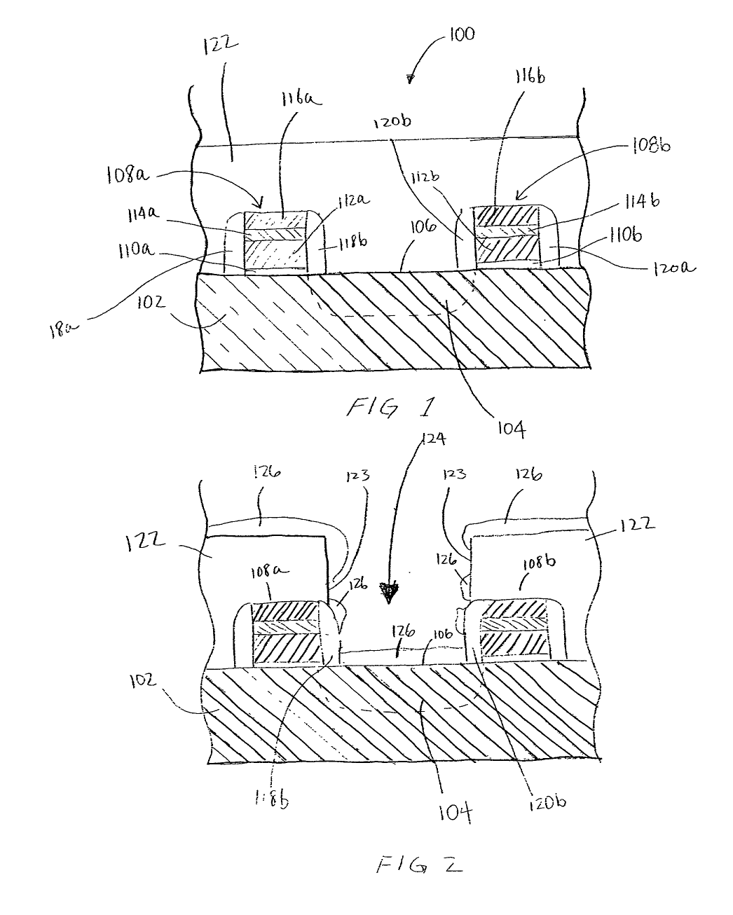

FIG. 1 illustrates a schematic sectional view of a semiconductor structure 100 of the preferred embodiment. As FIG. 1 shows, the semiconductor structure 100 generally comprises a substrate 102 having a highly doped silicon active area 104, which may comprise a transistor source or drain, defined below an upper surface 106 of the substrate 102. Furthermore, two gate structures 108a, 108b are formed over the silicon substrate 102 adjacent the active area 104. Each of the gate structures 108a, 108b has a thin gate oxide layer 110a, 110b, a polysilicon gate electrode layer 112a, 112b, a metallic layer 114a, 114b, a protective cap layer 116a, 116b, and side wall spacers 118a, 118b, 120a, 120b to protect the gate structures. As FIG. 1 further shows, an insulating layer 122 is formed over the gate structures 108a, 108b and the active area 104 on the silicon substrate 102. Preferably, the insulating layer 122 is comprised of borophosphosilicate (BPSG) or other generally known insulating material.

With reference to FIG. 2, a contact opening 124 is formed through the insulating layer 122 over the active area 104 to provide electrical contact to the active area 104. Preferably, the contact opening 124 is defined by the insulating layer 122, inner side wall spacers 118b, 120b, and the active area 104. In one embodiment, the contact opening 124 has an aspect ratio of at least 10:1. In another embodiment, the contact opening 124 has an aspect ratio of at least 5:1. As FIG. 2 further shows, a layer of metal 126 is subsequently formed in the contact opening 124 and over the insulating layer 122. In one embodiment, the metal layer 126 comprises titanium (Ti). As shown in FIG. 2, most of the Ti is formed over an upper surface 106 of the active area 104 or junction region and the insulating layer 122 surrounding the contact opening 124 although some remaining titanium may also form on the side walls 123 of the contact opening 124 during the deposition process. Preferably, Ti is deposited using a plasma enhanced chemical vapor deposition (PECVD) process. In one embodiment, the PECVD process uses a gas mixture comprised of TiCl₄, Ar, H₂, and He. Furthermore, the reaction gas temperature is preferably about 650° C., the RF power is approximately 400 W and the chamber pressure is about 4 Torr.

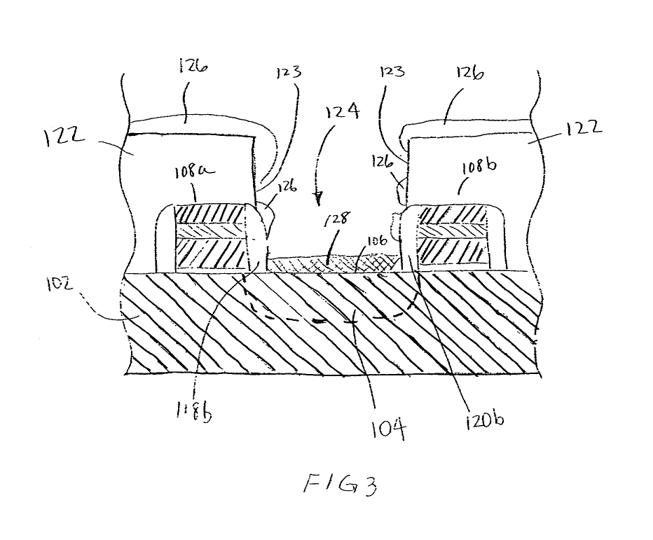

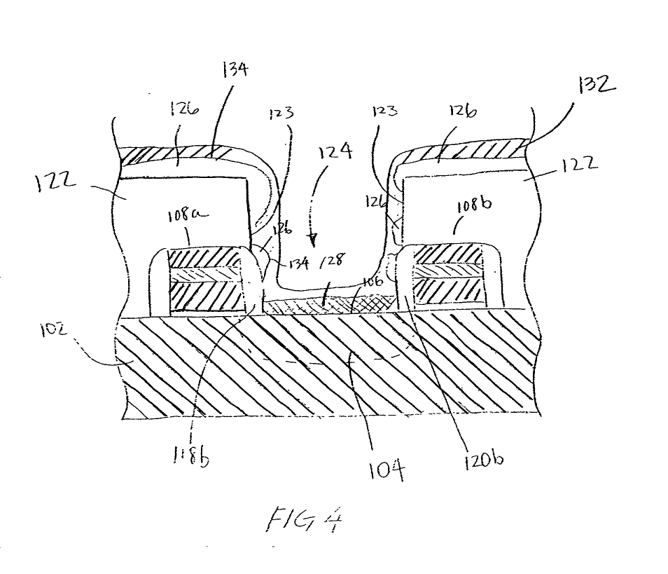

The metal layer 126 is subsequently annealed during which the metal formed on the substrate surface 106 above the active area 104 reacts with silicon in the substrate 104 to form a layer of metal silicide 128 as shown in FIG. 3. As previously discussed, the metal silicide layer 128 is formed to provide low resistance electrical contacts between device active regions within the silicon substrate, particularly in high aspect ratio contact areas where the contact resistance is relatively high. In one embodiment, the metal silicide layer 128 comprises titanium silicide (TiSiₓ). As shown in FIG. 3, the TiSiₓ layer 128 is formed over areas where Ti has contact with silicon in the substrate while portions of the Ti layer 126 deposited on the insulating layer 122 and sidewalls 123 of the contact opening 124 remains unreacted.

In an alternative embodiment, during deposition of the metal layer 126, the metal can be doped with a small amount of silicon to form the metal silicide layer 128 on the substrate surface 106. In a preferred embodiment, titanium doped with silicon is deposited on the substrate surface by a PECVD process using a mixture comprising TiCl₄, Ar, H₂, He, and SiH₄. In one embodiment, the process temperature is 650° C., RF power 400 W and chamber pressure 4 Torr. Preferably, a small amount of about 10 sccm of SiH₄ is added to the gas mixture at about 400 W. Preferably, the process deposits a titanium rich layer interspersed with TiSiₓ formed by reactions between the deposited silicon and some of the titanium.

This embodiment is particularly useful for forming contact structures over shallow junction regions where titanium may consume sufficient silicon from the junction region to adversely affect the electrical integrity of the contact. In particular, leakage in the junction can occur when a disproportionate amount of silicon is consumed by the titanium. Advantageously, doping titanium with a small amount of silicon reduces consumption of silicon from the junction region and produces a titanium rich TiSiₓ film having improved chemical and mechanical properties. Furthermore, the silicon doped titanium layer does not appear to affect the electrical integrity of the contact.

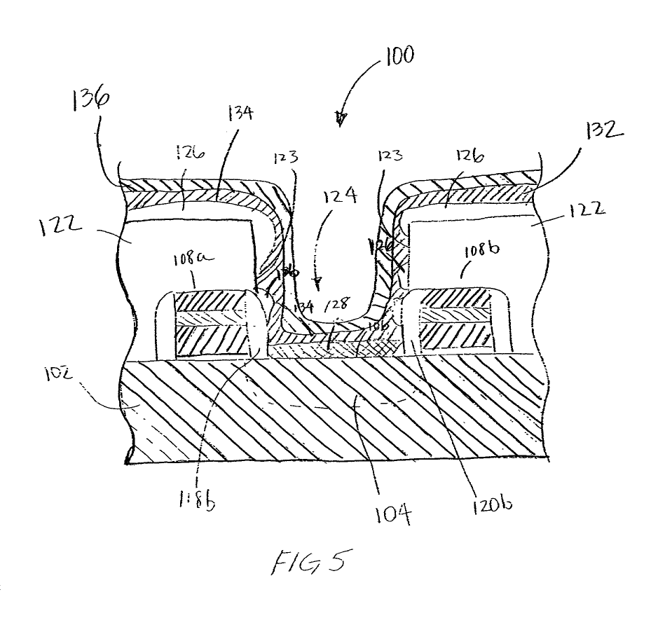

With reference to FIG. 4, subsequent to forming the metal silicide layer 128 adjacent the active area 104, a metal silicide adhesion layer 132 is formed on an upper surface 134 of the titanium film 126 deposited on the insulating layer 122 and side walls 123 of the contact opening 124. In one embodiment, the metal silicide adhesion layer is approximately 100 Å thick.

The metal silicide adhesion layer 132 preferably comprises TiSiₓ that is deposited by a PECVD process using a gas mixture comprising SiH₄, TiCl₄, Ar, H₂, and He. In one embodiment, the TiSiₓ adhesion layer 132 is deposited at a temperature of about 650° C., RF power of about 400 W and chamber pressure of about 4 Torr. Preferably, approximately 10 sccm of SiH₄ is introduced to the reaction process at about 400W as a source of Si. In one embodiment, the TiSiₓ adhesion layer 132 is formed on the previously deposited Ti film 126 to promote adhesion between the Ti film 126 and a subsequently deposited contact fill. According to one theory, the Ti layer 126 contains an appreciable amount of chlorine that is left over from the PECVD reaction gas. It is believed that the chlorine present in the Ti layer tends to inhibit formation of stable chemical and mechanical bonds with TiN. The TiSiₓ adhesion layer on the other hand contains far less chlorine than the Ti layer and has chemical and mechanical properties that are more conducive to forming strong and stable bonds with TiN. In one embodiment, the TiSiₓ adhesion layer can be formed immediately following the Ti deposition process using the same equipment and substantially the same process parameters.

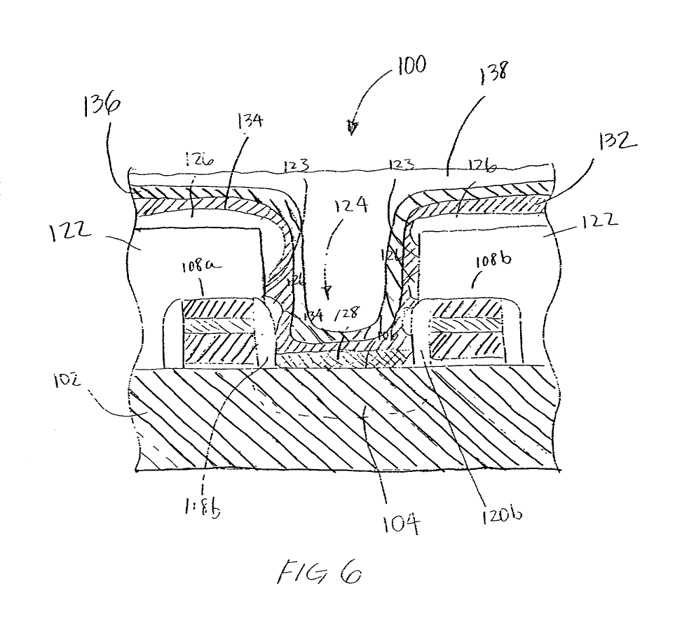

As illustrated in FIG. 5, following the formation of the TiSiₓ adhesion layer 132, a metal nitride diffusion barrier layer 136 is formed on the TiSiₓ adhesion layer 132. Preferably, the metal nitride layer 136 comprises TiN that is deposited by a thermal CVD process from TiCl₄ and NH₃ precursors. In one embodiment, the processing temperature is approximately 600 C. The metal nitride layer 134 is typically used as a barrier layer against junction spiking and diffusion of metal into the insulating layers. As such, it is desirable for the metal nitride layer to form a stable and durable bond with the contact structure.

However, as previously discussed, metal nitrides layers such as TiN generally do not adhere well to the Ti metal 126 deposited on the sidewalls 123 of the contact structure and top surface of dielectric. Consequently, the weak and unstable bonding between TiN and Ti often leads to TiN peeling off from the sidewalls 123 of the contact structure and top surface of dielectric, particularly at locations where TiN makes contact with Ti. Advantageously, the contact structure 100 of the preferred embodiment interposes the TiSiₓ adhesion layer 132 between the Ti 126 and TiN 136 layers whereby the TiSiₓ serves as a “glue” that bonds together the Ti and TiN layers. As such, the adhesion between TiN and Ti layers can be substantially improved and the occurrence of TiN peeling is substantially reduced. Furthermore, the formation of the TiSiₓ adhesion layer also eliminates the separate process that would otherwise be required to remove the remaining Ti film 126 from the sidewalls 123 of the contact opening 124 and top surface of the dielectric. Thus, the contact structure of the preferred embodiment provides a high aspect ratio opening with uniform metal coverage and superior adhesion of diffusion barrier layer and can be manufactured efficiently and cost-effectively.

Subsequent to forming the TiN diffusion barrier layer, a contact fill 138 is deposited in the contact opening 124 as shown in FIG. 6. In one embodiment, the contact fill 138 can comprise a metal such as tungsten or copper and can be deposited using a physical deposition process such as sputtering. In another embodiment, the contact fill 138 is comprised of TiN that can be deposited using a PECVD process from precursors such as TiCl₄ and TiI₄. Advantageously, contact fills comprised of TiN are particularly suited for high aspect ratio contact openings as the TiCl₄ and TiN fill can be deposited using, for example, chemical vapor deposition techniques which provide superior step coverage. Furthermore, contact fills comprised of TiCl₄ TiN also have superior electrical conductivity when compared with most other conventional contact fill materials.

As described above, the contact structures of the preferred embodiments utilize a metal silicide adhesion layer to improve the adhesion between the metal and metal nitride layer in a contact structure. The metal silicide adhesion film can be fabricated cost effectively using existing equipment and processes. The preferred contact structures also utilize a chemically deposited metal nitride as contact fill so as to improve the step coverage of the contact fill. The improved step coverage is particularly desirable for high aspect ratio contact openings in which superior step coverage is difficult to achieve when using conventional metal contact fills. Moreover, the contact structures of the preferred embodiments also comprise a titanium rich titanium silicide layer that is formed without consuming a significant amount of silicon from the contact junction regions, which is particularly desirable for shallow junction regions that can be easily damaged during the conventional silicidation process.

Although the foregoing description of the preferred embodiment of the present invention has shown, described and pointed out the fundamental novel features of the invention, it will be understood that various omissions, substitutions, and changes in the form of the detail of the apparatus as illustrated as well as the uses thereof, may be made by those skilled in the art, without departing from the spirit of the invention. Consequently, the scope of the invention should not be limited to the foregoing discussions, but should be defined by the appended claims.

What is claimed is:

1. An integrated circuit comprising:
a silicon substrate;
an insulating layer formed over the silicon substrate wherein the insulating layer has an opening that extends from an upper surface of the insulating layer to an upper surface of the substrate so as to expose the upper surface of the substrate;
a metal layer formed in the opening wherein a first portion of the metal layer is formed on the exposed upper surface of the substrate and reacts with silicon in the substrate to form metal silicide, wherein a second portion of the metal layer does not contact the substrate and remains unreacted; and
a metal nitride layer formed over the first and second portions of the metal layer in a manner such that a metal silicide adhesion layer is interposed between the metal nitride and the second portion of the metal layer so as to enhance adhesion between the metal nitride and the second portion of the metal layer.

2. The integrated circuit of claim 1, wherein the metal layer comprises titanium.

3. The integrated circuit of claim 2 wherein the metal nitride layer comprises titanium nitride.

4. The integrated circuit claim 3 wherein the metal silicide adhesion layer comprises titanium silicide.

5. The integrated circuit of claim 1 wherein the metal silicide adhesion layer contains less chlorine than the second portion of the metal layer, wherein the lower chlorine content in the metal silicide adhesion layer permits the metal silicide adhesion layer to bond the metal nitride with the second portion of the metal layer.

6. The integrated circuit of claim 4 wherein the metal silicide adhesion layer is approximately 50-150 Å thick.

7. The integrated circuit of claim 1 wherein the opening is a contact opening.

8. The integrated circuit of claim 1, wherein the contact opening has an aspect ratio of at least 10:1.

9. The integrated circuit of claim 8 wherein the exposed upper surface of the substrate comprises a junction region.

10. The integrated circuit of claim 9 further comprising a contact fill formed on an upper surface of the titanium nitride layer wherein the contact fill substantially fills the contact opening.

11. The integrated circuit of claim 10 wherein the contact fill comprises titanium nitride.

12. The integrated circuit of claim 11 wherein the titanium nitride contact fill comprises TiCl₄ based titanium nitride.

13. The integrated circuit of claim 10 wherein the contact fill comprises tungsten.

14. A high aspect ratio contact structure formed over a junction region in a silicon substrate, comprising:
an insulating layer, wherein the insulating layer defines a contact opening, wherein the contact opening is formed over the junction region of the substrate;
a titanium layer formed in and adjacent the contact opening, wherein a portion of the titanium layer is formed on the insulating layer;
a titanium silicide adhesion layer formed on an upper surface of the titanium layer;
a titanium nitride contact fill formed in and adjacent the opening, wherein the titanium nitride is formed on an upper surface of the titanium silicide adhesion layer, wherein the titanium silicide adhesion layer adheres the titanium nitride contact fill to the portion of the titanium layer.

15. The contact structure of claim 14, wherein the contact opening has an aspect ratio of at least 10:1.

16. The contact structure of claim 14, wherein the titanium nitride contact fill comprises a TiCl₄ based titanium nitride.

17. The contact structure of claim 14, wherein the insulating layer comprises BPSG.

18. The contact structure of claim 14, wherein the titanium silicide adhesion layer is approximately 50-150 Å thick.

19. The contact structure of claim 14, wherein the titanium silicide adhesion layer comprises a titanium rich layer interspersed with titanium silicide.

20. The contact structure of claim 14, wherein the titanium silicide adhesion layer comprises less chlorine than the titanium layer.

21. A method of forming a contact structure on a silicon substrate, comprising:
forming an insulating layer on an upper surface of the substrate;
forming an opening in the insulating layer, wherein the opening extends from an upper surface of the insulating layer to the upper surface of the substrate;
forming a titanium layer in and adjacent the opening, wherein a first portion of the titanium layer is formed on the upper surface of the substrate and a second portion of the titanium layer is formed on the upper surface of the insulating layer adjacent the opening;
reacting the first portion of the titanium layer with silicon in the substrate so as to form a titanium silicide layer adjacent the upper surface of the substrate;
forming a titanium silicide adhesion layer over the second portion of the titanium layer; and
forming a titanium nitride layer on an upper surface of the titanium silicide adhesion layer, wherein the titanium silicide adhesion layer bonds the titanium nitride layer to the second portion of the titanium layer.

22. The method of claim 21, wherein forming a titanium layer in and adjacent the opening comprises depositing a titanium layer using a PECVD process.

23. The method of claim 22, wherein depositing the titanium layer comprises using a gas mixture comprised of TiCl₄, Ar, H₂, and He.

24. The method of claim 23, wherein depositing the titanium layer comprises using a reaction gas temperature of about 650° C., RF power of about 400 W, and pressure of about 4 Torr.

25. The method of claim 21, wherein reacting the first portion of the titanium layer with silicon comprises using an annealing reaction.

26. The method of claim 21, wherein forming a titanium silicide adhesion layer comprises depositing a layer of titanium silicide using a PECVD process.

27. The method of claim 26, wherein depositing the titanium silicide adhesion layer comprises using a gas mixture comprising TiCl₄, Ar, H₂, He, and SiH₄.

28. The method of claim 27, wherein depositing the titanium silicide adhesion layer comprises adding about 10 sccm SiH₄ to the gas mixture at about 400 W.

29. The method of claim 28, wherein depositing the titanium silicide adhesion layer comprises using reaction gas temperature of about 650° C., RF 400W, and pressure of about 4 Torr.

30. The method of claim 21, wherein forming a titanium nitride layer comprises depositing a titanium nitride layer using a thermal CVD process from TiCl₄ and NH₃ precursors.

31. The method of claim 30, wherein depositing the titanium nitride layer comprises using a process temperature of about 600° C.

32. The method of claim 21, further comprising forming a contact fill in opening.

33. The method of claim 33, wherein forming the contact fill comprises depositing a metal in the opening.

34. The method of claim 34, wherein forming the contact fill in the opening comprises using a chemical vapor deposition process.

35. The method of claim 35, wherein forming the contact fill in the opening comprises depositing a titanium nitride contact fill, wherein the titanium nitride fills substantially the entire opening.
